(19) United States
(12) Patent Application Publication
(10) Pub. No.: US 2017/0243776 A1
(43) Pub. Date: Aug. 24, 2017

(54) Purge Device and Purge Method

(71) Applicant: Murata Machinery, Ltd., Kyoto-shi, Kyoto (JP)

(72) Inventors: Masanao MURATA, Ise-shi, Mie (JP); Takashi YAMAJI, Ise-shi, Mie (JP)

(73) Assignee: Murata Machinery, Ltd., Kyoto-shi, Kyoto (JP)

(21) Appl. No.: 15/305,637

(22) PCT Filed: Dec. 3, 2014
(86) PCT No.: PCT/JP2014/081944

§ 371 Date: Oct. 20, 2016

(30) Foreign Application Priority Data
Feb. 27, 2014 (JP) 2014-036602

(51) Int. Cl. H01L 21/673; H01L 21/677; H01L 21/67

(52) U.S. Cl. CPC H01L 21/67389; H01L 21/67379; H01L 21/67017; H01L 21/67769; H01L 21/67772

(57) ABSTRACT

A container is placed at a predetermined position on a purge device to prevent the container from getting caught on a nozzle. When the container is lowered and placed on the purge device, the two facing sides of the front end of the container's bottom surface and the front end of a recessed part, and the two facing sides of both left and right side ends of the container's bottom surface are guided by a front guide, side guides and a center guide. Following that, the nozzle is brought into contact with the bottom surface of the container.

### TECHNICAL FIELD

The present invention relates to a device for purging a container such as a FOUP (Front Opening Unified Pod) and a purge method.

### BACKGROUND ART

A purge gas such as a nitrogen gas or a clean dry air is injected through a nozzle into a container such as a FOUP that houses a semiconductor wafer, and thereby the inside of the container is purged. The position of the container is determined by engaging a pin with a recessed part for positioning located at the bottom surface of the container, however there are some containers in which the depth of a receiving hole of a nozzle is deeper than the recessed part for positioning. In such a container, the height of the nozzle becomes taller than the pin, so that the container gets caught on the nozzle, preventing it from being positioned.

Patent literature 1 (JP2011-187539) suggests that an actuator which raises and lowers a nozzle is provided on a purge device to determine the position of a container by using a pin in a state wherein the nozzle is being lowered and then subsequently raise the nozzle.

### CITATION LIST

### Patent Literature

[Patent Literature 1] JP2011-187539

### SUMMARY OF INVENTION

### Technical Problem

In such a manner suggested in Patent Literature 1, the actuator is required to raise and lower the nozzle, thereby creating a complicated structure of the purge device. Moreover, there is a need to control the actuator, and it becomes troublesome to perform, for example, adjustment and maintenance of the actuator.

An object of the present invention is to be able to place a container at a predetermined position on a purge device without relying on an actuator and without the container getting caught on a nozzle.

### Solution to Problem

The present invention provides a purge device that has a nozzle for supplying a purge gas into a container, and the purge device includes: a front guide for guiding the front end of the bottom surface of the container; a pair of left and right side guides for guiding both left and right side ends of the bottom surface of the container; and a center guide for guiding the front end of a recessed part located on the center part of the bottom surface of the container. The front guide, side guides and center guide are all configured to start guiding the container from a position higher than the nozzle.

The present invention also provides a purge method in which a purge gas is supplied through a nozzle on a purge device into a container, wherein the purge device are provided with: a front guide for guiding the front end of the bottom surface of the container; a pair of left and right side guides for guiding both left and right side ends of the bottom surface of the container; and a center guide for guiding a recessed part located on the center part of the bottom surface of the container. The front guide, side guides and center guide are all taller than the nozzle. The purge method comprises the steps of: having the front guide, side guides and center guide guide the two facing sides of the front end of the container's bottom surface and the front end of the recessed part, and the two facing sides of both left and right side ends of the container's bottom surface when the container is lowered and placed on the purge device; and bringing the nozzle into contact with the bottom surface of the container after having started guiding the two facing sides of the front end of the container's bottom surface and the front end of the recessed part, and the two facing sides of both left and right side ends of the container's bottom surface.

In the present invention, the front guide, side guides and center guide guide the two facing sides of the front end of the container's bottom surface and the front end of the recessed part, and the two facing sides of both left and right side ends of the container's bottom surface, so that the container can be guided almost to the correct position. This can prevent the nozzle from getting caught on the bottom surface of the container and from not enabling the placement in the predetermined position. The present invention does not require an actuator which raises and lowers the nozzle, and there is also no need to control, adjust and maintain the actuator. Here, the height (tall/short) described in this specification is determined according to the height above a horizontal reference surface.

Preferably, the container subject to purging is provided on the bottom surface with: a receiving hole for receiving the nozzle; and a plurality of recessed parts for positioning. The purge device further includes a plurality of fixed positioning pins which are shorter than the nozzle. The purge device is configured in such a way that by having the container guided by the front guide, side guides and center guide, the nozzle is received in the receiving hole, the positioning pin is engaged with the recessed part for positioning, and the position of the container is determined to the purge device. Thus, even when the nozzle impedes the positioning because the nozzle is taller than the positioning pin, the nozzle is housed in the receiving hole and the position can be determined by the positioning pin after the container has been guided almost to the correct position by the guides.

In addition, the center guide is preferably configured to be freely lowered by the weight of the container. This can prevent a head of the center guide from touching the bottom of the recessed part and from not enabling the container to be lowered. The depth of the recessed part may vary.

The nozzle is preferably configured to be freely lowered by the weight of the container. This can surely prevent the pin from not being able to carry out the positioning due to the height of the nozzle.

The nozzle preferably includes a guide surface at the upper part and is configured in such a way that the guide surface guides the receiving hole. Thus, the guide surface can resolve the nozzle and the receiving hole being caught on each other.

A base is preferably further included, the front guide, side guides, center guide, nozzle and nozzle are attached to the base, and the nozzle is attached to the base as such to be freely tilted via an elastic spacer. Thus, if the nozzle is not evenly in contact with the receiving hole, the nozzle is tilted, thereby bringing it evenly in contact with the receiving hole.

### BRIEF DESCRIPTION OF DRAWINGS

FIG. 1 is a bottom view of a FOUP.

FIG. 2 is a plan view of a purge device according to one embodiment.

FIG. 3 is a plan view of a center guide.

FIG. 4 is a side view of the center guide.

FIG. 5 is a side view of a nozzle.

FIG. 6 is a cross-sectional view showing the purge device and the FOUP that is being lowered.

### DESCRIPTION OF EMBODIMENTS

A preferred embodiment of the present invention will be explained hereinafter. The scope of the invention shall be determined in accordance with the understanding of a person having ordinary skill in the art, while taking into consideration the description in the specification and a well-known art in this field based on the description in the scope of claims.

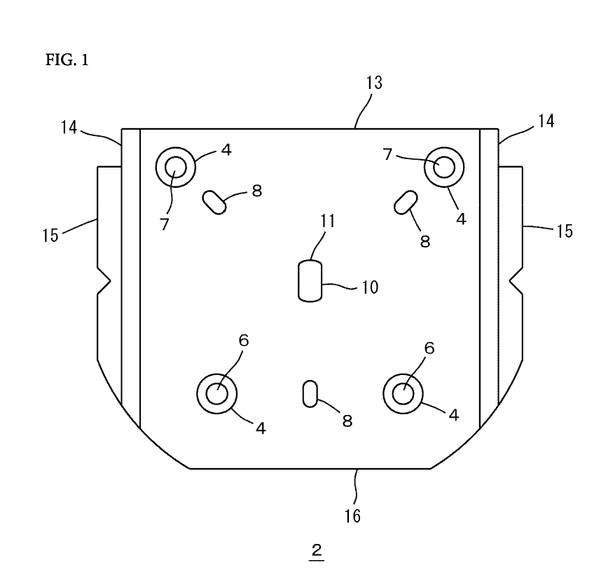

FIGS. 1-6 show a purge device 20 of the embodiment. FIG. 1 shows a bottom surface of a FOUP 2 that is subject to purging, and a purge gas refers to nitrogen, a clean dry air, or the like. A container which is purged is not limited to a FOUP, and an article which is housed in the container is not limited to a semiconductor wafer, but for example, a reticle may be used. The FOUP 2 includes, for example, four receiving holes 4 which receive nozzles of the purge gas, and valves 6, 7 are provided at the bottom part of the receiving holes 4. The valve 6 is used for injecting the purge gas, and the valve 7 is used for discharging the gas, however the valves 6, 7 may not be required.

According to international standards on the FOUP 2, three coupling grooves 8 are provided, and a front reference surface 13 and a side reference surface 14 have the standardized position. 15 is a forklift flange, 16 is a rear surface of the FOUP 2, and the position of the rear surface 16 is not specified in the international standards. The front reference surface 13 is a surface to which a lid of the FOUP 2 is attached, and this specification regards the front reference surface 13 as being located at the front of the FOUP 2 and the rear surface 16 as being located at the back of the FOUP 2. In addition, a direction of connecting both lateral sides of the FOUP 2 is called left and right. The international standards define that a center groove 10 is provided at a predetermined position on the center part of the bottom surface in order to set the FOUP 2 in place and also specify the positions of the front and rear surfaces of the center groove 10. And with that, the front surface of the center groove 10 is regarded as a reference surface 11, and the lower end of the reference surface 11 is used for guiding the FOUP 2. However, the depth of the receiving hole 4 and the center groove 10 vary. Here, when the purge nozzle becomes taller than the coupling pin because the receiving hole 4 is deeper than the coupling groove 8, the preferred embodiment is suitably used.

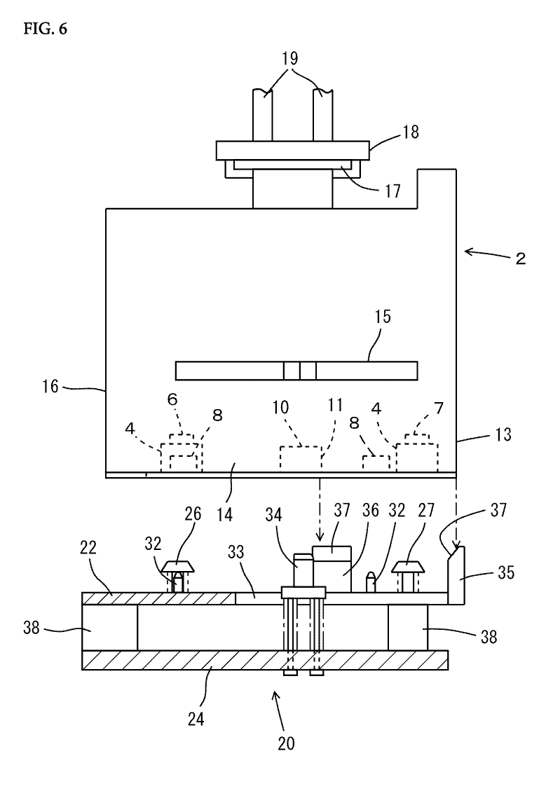

As shown in FIG. 6, the FOUP 2 includes a top flange 17 on an upper part, the top flange 17 is chucked by a lifting platform 18 of an overhead traveling vehicle not illustrated, and the FOUP 2 is elevated and lowered by a belt 19.

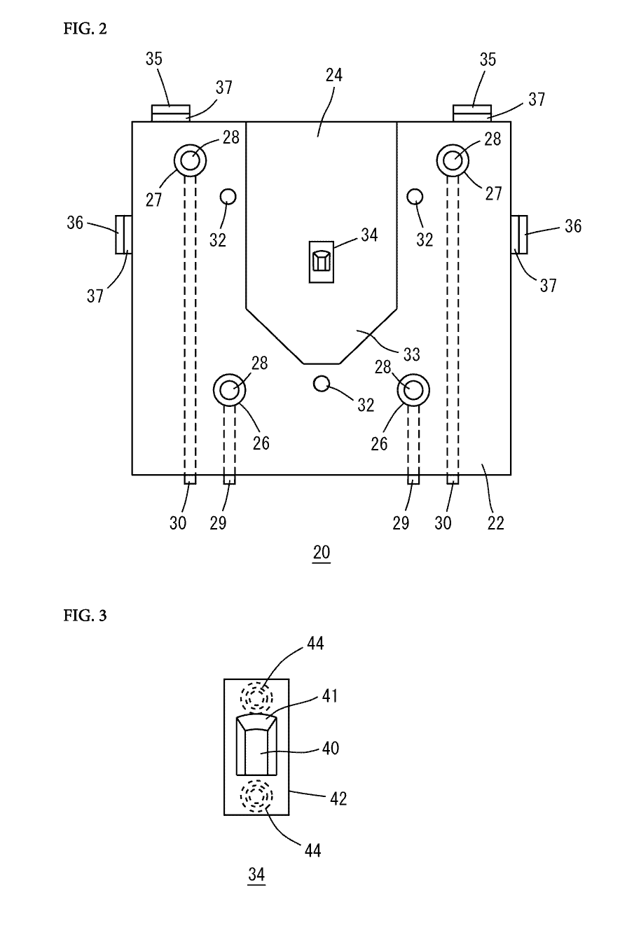

FIGS. 2-5 show the structure of the purge device 20. The purge device 20 is configured in such a way that the overhead traveling vehicle freely transfers the FOUP 2 and a transfer apparatus equipped with an arm that is capable of elevating/lowering and moving back and forth the FOUP 2 without any impediments also freely transfers the FOUP 2. The purge device 20 is used, for example, in a stocker for storing the FOUP 20, a buffer for being located in the vicinity of a track of the overhead traveling vehicle and a buffer for being located on the front surface of a processing device, and a purge gas source not illustrated is provided separately.

22 is a base, and the FOUP 2 is placed on the upper surface of the base. 24 is a lower plate, 26 and 27 are purge nozzles, the nozzle 26 is used for injecting the purge gas, the nozzle 27 is used for discharging the gas, and the nozzle 27 may not be required. In addition, one to three nozzles 26 are provided. Preferably, a guide surface 28, which is formed of a fine tapered surface, is provided on the upper part of the nozzles 26, 27 and guides the receiving hole 4 of the FOUP 2. 29 is a pipe used for injecting the purge gas, and 30 is an exhaust pipe and may not be required.

In order to guide the lower end of the front reference surface 13 of the FOUP 2 (front end of the bottom surface), for example, a pair of front guides 35 is set protruded from the base 22. In addition, in order to guide the lower end of the side reference surfaces 14 (left and right ends of the bottom surface), at least a pair of left and right side guides 36 is set protruded from the base 22. Hereinafter, the front guide 35 is simply referred to as a guide 35 and the side guide 36 is simply referred to as a guide 36. The guides 35, 36 include guide surfaces 37 that are formed of tapered surfaces and guide the lower ends of the reference surfaces 13, 14 of the FOUP 2.

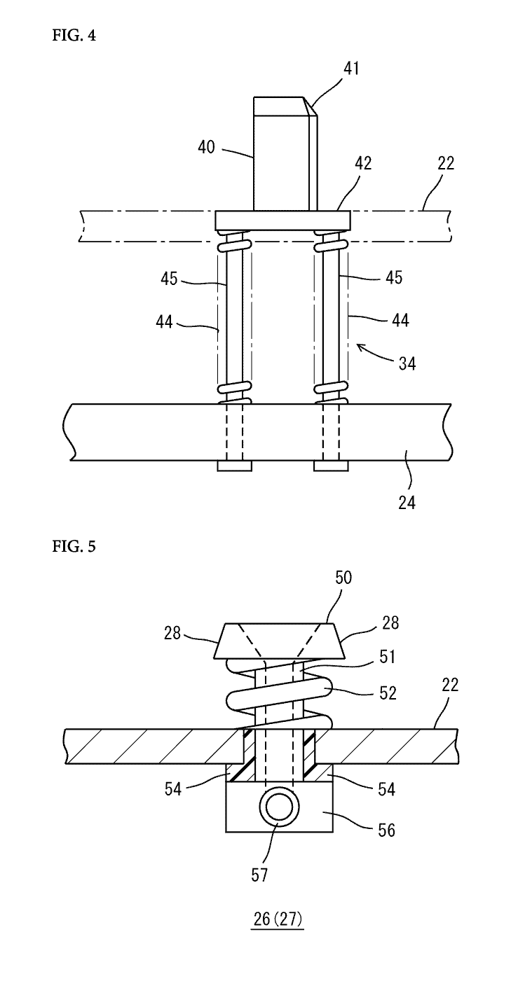

For example, three pins 32 are provided on the base 22 to kinematically couple with the coupling grooves 8 on the FOUP 2 and then determine the position of the FOUP 2. In addition, a center guide 34 protrudes, for example, from the lower plate 22 above a notch 33 on the base 22 in order to guide the lower end of the reference surface 11 of the center groove 10 on the FOUP 2. With respect to the height using the upper surface of the base 22 as reference, the guide surface 37 and a guide surface 41 of the center guide 34 (FIGS. 3 and 4) are the tallest followed by the nozzles 26, 27, and the pin 32 is the shortest. As shown in FIG. 6, the base 22 and the lower plate 24 are connected by a support part 38.

FIGS. 3 and 4 show the structure of the center guide 34. A protruding part 40 protrudes so as to engage with the center groove 10 on the FOUP 2, and the guide surface 41 that is formed of a tapered surface is provided in such a way as to guide the lower end of the reference surface 11, for example. The protruding part 40 is fixed to a pedestal 42, and is mounted on the lower plate 24 so as to be freely lowered by, for example, a pair of pins 45 attached to the pedestal 42, and is urged upward by, for example, a pair of elastic bodies 44 such as springs. The reason for allowing the protruding part 40 to be freely lowered is because the depth of the center groove 10 on the FOUP 2 varies. If the upper part of the protruding part 40 does not interfere with the bottom part of the center groove 10, the height of the protruding part 40 may be fixed. To cope with the center groove 10 having various depths, it is preferred that the protruding part 40 is urged upward by the elastic body and can be freely lowered by the weight of the FOUP 2.

FIG. 5 shows the preferred embodiment of the nozzles 26, 27. 50 is a head of the nozzle which is brought into close contact with the bottom part of the receiving hole 4, thereby maintaining the airtightness. A hollow shaft 51 extends downward and connects to a pedestal 56. The head 50 is urged upward by an elastic body 52 such as a spring and can be freely lowered by the weight of the FOUP 2. In addition, an elastic spacer 54 such as a synthetic resin is positioned between the base 22 and the pedestal 56, and it allows the head 50 to be tilted from the vertically upward position. 57 is a connection part with the pipe. It is preferred that the nozzles 26, 27 are urged upward by the elastic body and can be freely lowered by the weight of the FOUP 2. Additionally, the direction of the nozzle (the direction of the nozzle axis) can preferably be tilted from the vertically upward position.

FIG. 6 shows the positioning of the FOUP 2. When the FOUP 2 is being lowered, the nozzle 26 gets caught on the receiving hole 4 without the guide 35 or the like as the nozzle 26 is taller than the pin 32, whereby the pin 32 may not be able to do the guide. Therefore, the guides 35, 36 are provided to guide three sides of the lower ends of the front reference surface 13 and the side reference surfaces 14 of the FOUP 2. In addition, the center guide 34 guides the lower end of the reference surface 11 of the FOUP 2. This enables the FOUP 2 to be guided almost to the correct position, and thereby the chance of being caught on the nozzles 26, 27 is reduced. If the center groove 10 is shallow, the protruding part 40 of the center guide 34 contacts the bottom part of the center groove 10, thereby lowering the protruding part 40.

As shown in FIG. 5, the nozzles 26, 27 include the guide surface 28 on its upper part, preferably at its tip. Therefore, if the nozzles 26, 27 get caught on the receiving hole 4, the receiving hole 4 is guided along the guide surface 28, thereby resolving the nozzles being caught. In addition, since the nozzles 26, 27 can be freely lowered, the nozzles are lowered by the weight of the FOUP 2 and are lowered to a position where the positioning by the pin 32 is not hindered. Furthermore, if the nozzles 26, 27 are not evenly in contact with the receiving hole 4, unbalanced load is applied to the elastic spacer 54 and then the nozzles 26, 27 are tilted, thereby bringing them evenly in contact with the receiving hole 4.

The embodiment has the following characteristics:
1) The guide 35 and the center guide 34 guide the two facing sides of the lower end of the front reference surface 13 of the FOUP 2 (front end of the bottom surface) and the lower end of the reference surface 11 of the center groove 10. Additionally, a pair of left and right guides 36 guide the lower ends of the left and right side reference surfaces 14 (left and right ends of the bottom surface), so that the chance of the FOUP 2 and nozzles 26, 27 being caught on each other is reduced.
2) The center guide 34 is lowered by the weight of the FOUP 2, and thereby the protruding part 40 of the center guide 34 does not impede lowering the FOUP2.
3) The guide surface 28 is capable of resolving the nozzles 26, 27 and the receiving hole 4 being caught on each other.
4) The nozzles 26, 27 are lowered by the weight of the FOUP 2 and do not impede the positioning by the pin 32.
5) If the nozzles 26, 27 are not evenly in contact with the receiving hole 4, the nozzles 26, 27 are tilted so as to come evenly in contact with the receiving hole.

When the transfer using an arm such as a stacker crane is not necessary, the lower plate 24 and the notch 33 on the base 22 are not required, so that the center guide 34 is supported by the base 22. In addition, when the purge device 20 is provided at a load port where the front lid of the FOUP 2 is opened/closed and a semiconductor wafer is deposited and retrieved into/from the FOUP, it is preferred that the guide 35 is freely elevated and lowered without impeding the opening and closing of the lid.

### REFERENCE SIGNS LIST

2 . . . FOUP, 4 . . . Receiving hole, 6, 7 . . . Valve, 8 . . . Coupling groove, 10 . . . Center groove, 11 . . . Reference surface, 13 . . . Front reference surface, 14 . . . Side reference surface, 15 . . . Forklift flange, 16 . . . Rear surface, 17 . . . Top flange, 18 . . . Lifting platform, 19 . . . Belt, 20 . . . Purge device, 22 . . . Base, 24 . . . Lower plate, 26, 27 . . . Nozzle, 28 . . . Guide surface, 29, 30 . . . Pipe, 32 . . . Pin, 33 . . . Notch, 34 . . . Center guide, 35 . . . Front guide, 36 . . . Side guide, 37 . . . Guide surface, 38 . . . Support part, 40 . . . Protruding part, 41 . . . Guide surface, 42 . . . Pedestal, 44 . . . Elastic body, 45 . . . Pin, 50 . . . Head, 51 . . . Hollow shaft, 52 . . . Elastic body, 54 . . . Elastic spacer, 56 . . . Pedestal, 57 . . . Connection part

1. A purge device that has a nozzle for supplying a purge gas into a container, the purge device comprising:
a front guide for guiding the front end of the bottom surface of the container;
a pair of left and right side guides for guiding both left and right side ends of the bottom surface of the container; and
a center guide for guiding the front end of a recessed part located on the center part of the bottom surface of the container;
wherein the front guide, side guides and center guide are all configured to start guiding the container from a position higher than the nozzle.

2. The purge device according to claim 1, wherein a container subject to purging is provided on the bottom surface with:
a receiving hole for receiving the nozzle; and
a plurality of recessed parts for positioning;
the purge device further comprising;
a plurality of fixed positioning pins which are shorter than the nozzle;
wherein the purge device is configured in such a way that by having the container guided by the front guide, side guides and center guide, the nozzle is received in the receiving hole, the positioning pin is engaged with the recessed part for positioning, and the position of the container is determined to the purge device.

3. The purge device according to claim 2, wherein
the center guide is configured to be freely lowered by the weight of the container.

4. The purge device according to claim 2, wherein
the nozzle is configured to be freely lowered by the weight of the container.

5. The purge device according to claim 2, wherein
the nozzle includes a guide surface at the upper part and is configured in such a way that the guide surface guides the receiving hole.

6. The purge device according to claim 2, wherein
a base is further included, the front guide, side guides, center guide, nozzle and nozzle are attached to the base, and the nozzle is attached to the base as such to be freely tilted via an elastic spacer.

7. A purge method in which a purge gas is supplied through a nozzle on a purge device into a container, the method performed by the purge device including:
a front guide for guiding the front end of the bottom surface of the container;
a pair of left and right side guides for guiding both left and right side ends of the bottom surface of the container; and
a center guide for guiding a recessed part located on the center part of the bottom surface of the container;
wherein the front guide, side guides and center guide are all taller than the nozzle;
the purge method comprising the steps of:
having the front guide, side guides and center guide guide the two facing sides of the front end of the container's bottom surface and the front end of the recessed part, and the two facing sides of both left and right side ends of the container's bottom surface when the container is lowered and placed on the purge device; and
bringing the nozzle into contact with the bottom surface of the container after having started guiding the two facing sides of the front end of the container's bottom surface and the front end of the recessed part, and the two facing sides of both left and right side ends of the container's bottom surface.
